(19) United States
(12) Patent Application Publication
(10) Pub. No.: US 2013/0206070 A1
(43) Pub. Date: Aug. 15, 2013

(54) DEPOSITION RING

(71) Applicant: WELL THIN TECHNOLOGY, LTD., (US)

(72) Inventor: Ben CHEN, Zhubei City (TW)

(73) Assignee: WELL THIN TECHNOLOGY, LTD., Zhubei City (TW)

(21) Appl. No.: 13/757,155

(22) Filed: Feb. 1, 2013

(30) Foreign Application Priority Data
Feb. 10, 2012 (TW) 101202451

(51) Int. Cl. C23C 16/458

(52) U.S. Cl. CPC C23C 16/458
USPC 118/728

(57) ABSTRACT

A deposition ring is used on thin film deposition equipment which includes a chuck to hold a wafer. The deposition ring is arranged on the circumferential wall of the chuck and includes an inner ring and a protective member. The inner ring is adjacent to the circumferential wall. The protective member is jutting from the inner ring and has a circumferential surface, a barrier surface and a tip edge. The circumferential surface opposes the circumferential wall. The barrier surface and circumferential surface form an acute angle between them. The tip edge is formed between the circumferential surface and barrier surface. Through the protective member, the probability of adhering deposition particles to the back of the wafer is greatly reduced. The protective member is formed in a structure with a gradually increasing bottom, hence can provide higher stress resistant capability and overcome the easy fracturing problem in the conventional techniques.

### FIELD OF THE INVENTION

The present invention relates to a semiconductor equipment component and particularly to a deposition ring.

### BACKGROUND OF THE INVENTION

Semiconductor industry is very much thriving these days. Thin film deposition technique is a manufacturing technique widely used in the semiconductor industry. The thin film deposition technique mainly can be divided mainly into physical vapor phase deposition by employing physical phenomenon and chemical vapor phase deposition by employing chemical reactions. It mainly aims to perform a deposition process in thin film deposition equipment.

The thin film deposition equipment employs an electrostatic chuck to hold a wafer intend for thin film deposition. The electrostatic chuck holds a deposition ring at the circumferential wall thereof to prevent deposition particles from adhering to the surface of the chuck, thereby to save cleaning time and cost, and improve production yield of thin film deposition.

For instance, U.S. Pat. No. 6,733,829 discloses an anti-binding deposition ring. The deposition ring has an inner circumferential edge adjacent to an electrostatic chuck, a contact surface connecting to the electrostatic chuck and a cut-out portion spaced from the electrostatic chuck at a selected distance. The contact surface can prevent deposition particles from binding the deposition ring and electrostatic chuck during deposition process and avoid damage of the electrostatic chuck.

However, the inner circumferential edge of the aforesaid deposition ring is prone to deform or fracture due to thermal expansion and cold contraction after being repeatedly used for a number of times. As a result, the service cycle is reduced. There is still room for improvement.

### SUMMARY OF THE INVENTION

The primary object of the present invention is to improve the deformation or fracture problem of the conventional deposition ring caused by thermal expansion and cold contraction or external stress that results in shortened service cycle.

To achieve the forgoing object, the present invention provides a deposition ring used on thin film deposition equipment. The thin film deposition equipment includes a chuck to hold a wafer. The deposition ring is arranged on a circumferential wall of the chuck and includes an inner ring and a protective member. The inner ring is adjacent to the circumferential wall. The protective member is jutting from the inner ring and has a circumferential surface, a barrier surface and a tip edge. The circumferential surface opposes the circumferential wall. The barrier surface and circumferential surface form an acute angle between them. The tip edge is formed between the circumferential surface and barrier surface.

Through the protective member, the tip edge can greatly reduce deposition of the particles behind the protective member, and also reduce the probability of indirectly adhering the deposition particles to the back of the wafer. Moreover, as the barrier surface and circumferential surface form the acute angle between them, a structure with a gradually increasing bottom is formed, hence also provides greater stress resistant capability and resolves the problem of easy fracturing.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1A is a top view of a first embodiment of the invention.

FIG. 1B is a sectional view of the first embodiment of the invention.

FIG. 2 is a schematic view showing the invention in the first embodiment disposed in thin film deposition equipment.

FIG. 3A is a sectional view of a second embodiment of the invention.

FIG. 3B is a fragmental enlarged view according to FIG. 3A.

FIG. 4A is a schematic view of a conventional deposition ring in a use condition.

FIG. 4B is a schematic view of the second embodiment of the invention in a use condition.

### DETAILED DESCRIPTION OF THE PREFERRED EMBODIMENTS

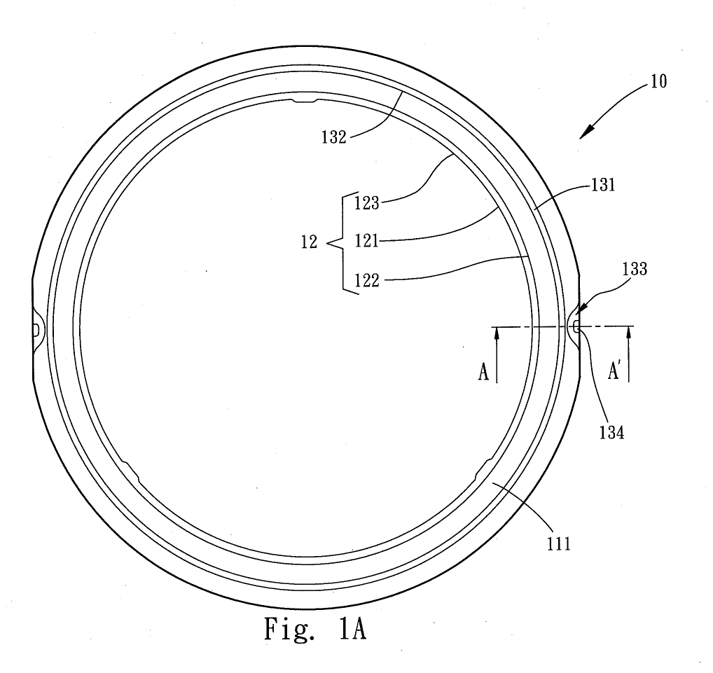

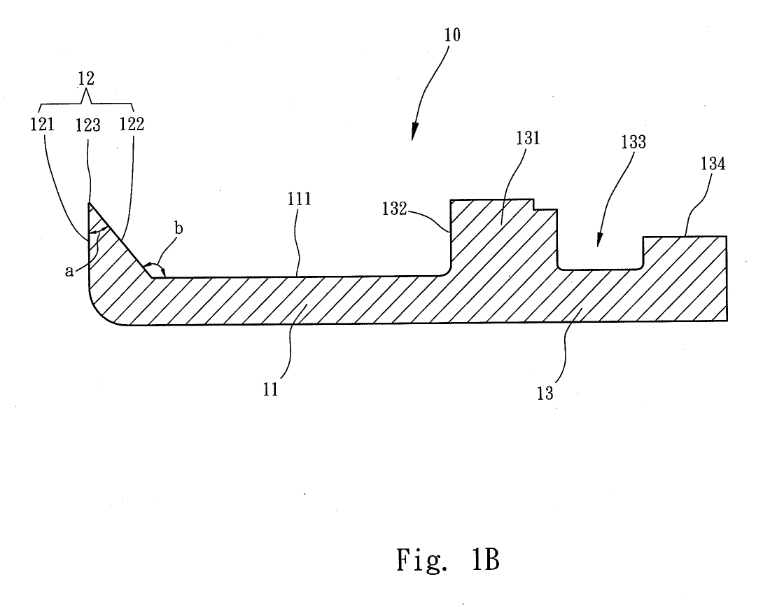

Please refer to FIGS. 1 A, 1B and 2 for a first embodiment of the invention. The invention provides a deposition ring 10 used on thin film deposition equipment. The thin film deposition equipment has a chuck 20 which includes a holding portion 21 and an extension 22 connecting to the holding portion 21. The holding portion 21 is higher than the extension 22 and has a circumferential wall 211. The chuck 21 can hold a wafer 30. The extension 22 holds the deposition ring 10. The deposition ring 10 surrounds the circumferential wall 211 and includes an inner ring 11, an outer ring 13 and a protective member 12. The inner ring 11 is adjacent to the circumferential wall 211. The outer ring 13 is connected to the outer ring 11 and is located at one side of the inner ring 11 remote from the circumferential wall 211. The protective member 12 is jutting from the inner ring 11 and includes a circumferential surface 121, a barrier surface 122 and a tip edge 123. The circumferential surface 121 opposes the circumferential wall 211. The barrier surface 122 and circumferential surface 121 form an acute angle a between them. The tip edge 123 is formed between the circumferential surface 121 and barrier surface 122. In this embodiment the circumferential surface 121 is a vertical surface parallel with the circumferential wall 211. The barrier surface 122 is, but not limited to, an inclined surface, and also can be a curved surface. The tip edge 123 is formed at an elevation lower than that of the wafer 30 and covered by the wafer 30 from the above.

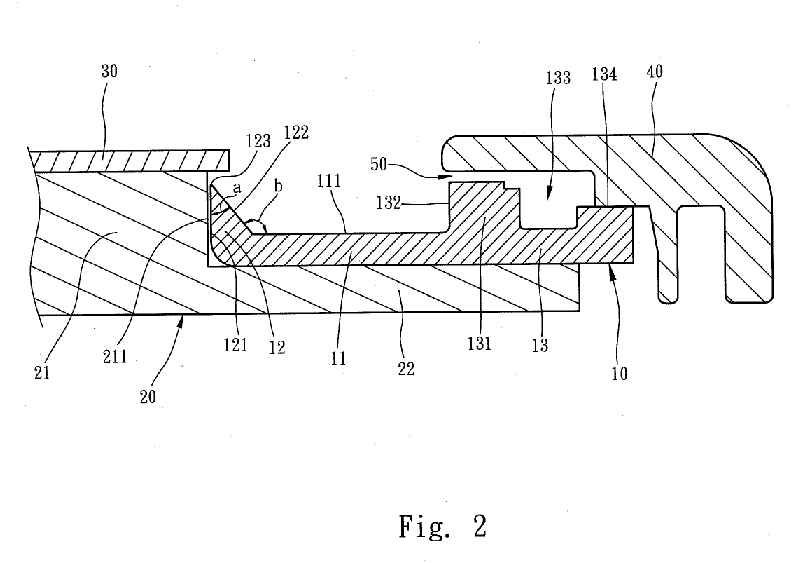

Furthermore, the inner ring 11 has an upper surface 111 adjacent to the protective member 12. The upper surface 111 is connected to the barrier surface 122 to form an obtuse angle b between them. The outer ring 13 has a jutting detent member 131 and an indented isolation groove 133. The detent member 131 is connected to the inner ring 11 and has a detent surface 132 connected to the upper surface 111. The detent surface 132 is perpendicular to the upper surface 111 at a selected upright height. The isolation groove 133 is adjacent to the detent member 131 and located at one side of the detent member 131 remote from the inner ring 11. In addition, in this embodiment as shown in FIG. 2, the deposition ring 10 is incorporated with a cover ring 40. The outer ring 13 has a juncture 134 at one side remote from the inner ring 11. The cover ring 40 is connected to the juncture 134. The detent member 131 and cover ring 40 form a route gap 50 between them to communicate with the isolation groove 133.

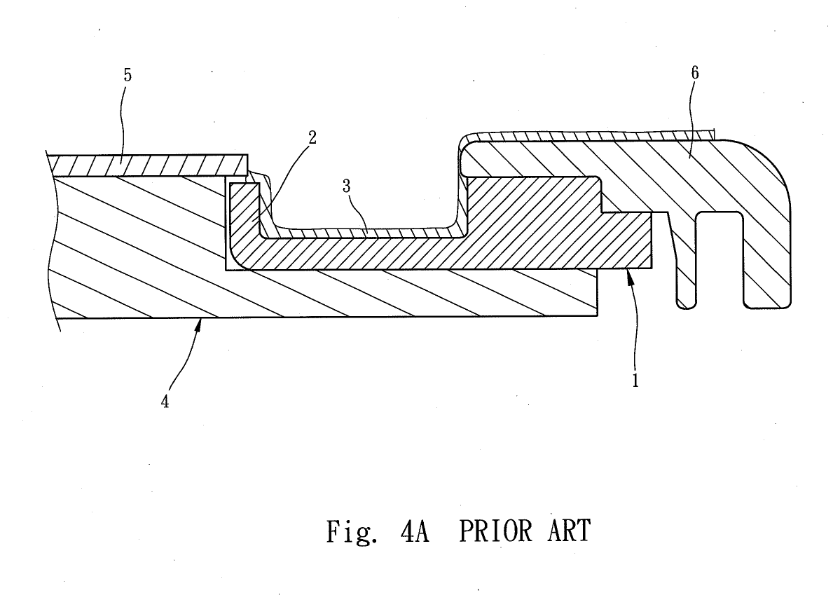

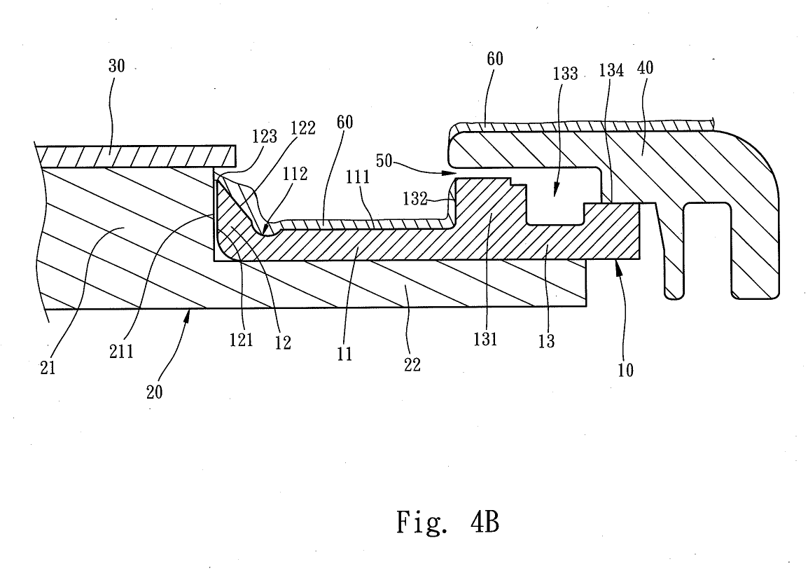

By means of the structure set forth above, when the thin film deposition equipment is in deposition operation, a plurality of deposition particles drop onto the protective member 12 without adhering to the back of the wafer 30 due to the barrier surface 122 which provides a reflective path for the deposition particles moving away from the wafer 30. When the deposition particles move towards the outer ring 13 the barrier surface 132 blocks a great portion of them, and only a small portion of them enter the route gap 50 in which the deposition particles generate multiple times of impact and result in loss of kinetic energy, and finally drop into the isolation groove 133 without reaching the juncture 134 of the deposition ring 10 and cover ring 40, or gaps of the juncture 134. Thus, by exhausting the kinetic energy of the deposition particles through the route gap 50, and providing a housing space for the deposition particles through the isolation groove 133, a deposition substance 60 (referring to FIG. 4B) formed from the deposition particles on the surfaces of the deposition ring 10 and cover ring 40 is broken off at the route gap 50. Thus the deposition particles cannot be deposited at the juncture 134 to form a continuous structure, hence can avoid generation of a conductive phenomenon.

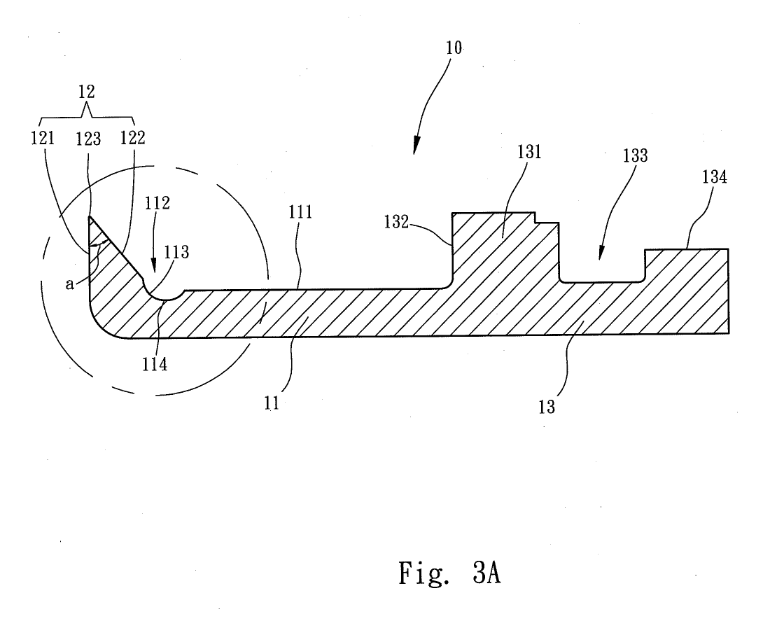

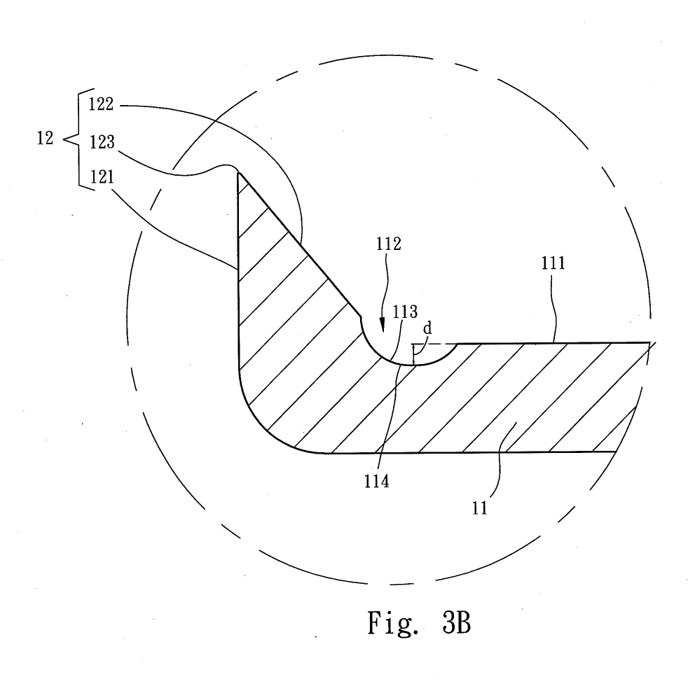

Please refer to FIGS. 3A and 3B for a second embodiment of the invention. It differs from the first embodiment by having a recess 112 on the inner ring 1 to bridge the barrier surface 122 and upper surface 111. The recess 112 has a concave surface 113 which is, in this embodiment, an arched surface, but this is not the limitation of the invention. The concave surface 113 has a bottom side 114 in the recess 112. The bottom side 114 is spaced from the upper surface 111 at a depth d. Thus a greater elevation difference is formed between the bottom side 114 and the back of the wafer 30. When the deposition particles drop around the protective member 12, a portion of them fill in the recess 112, hence the time of accumulating the deposition particles to contact the back of the wafer 30 is extended, thereby can further increase the service cycle of the deposition ring 10. Moreover, since the depth d correlates to the time of accumulation of the deposition particles to contact the back of the wafer 30, the depth d affects the service cycle of the deposition ring 10.

Please refer to FIG. 4A for a conventional deposition ring in a use condition and FIG. 4B for the second embodiment of the invention in a use condition. They have respectively a deposition ring 1 or 10 that have been used for deposition for a same number of times, and then a wafer 5 or 30 intended for deposition is placed thereon. As shown in FIG. 4A, the protective member 2 of the conventional deposition ring 1 has a deposition substance 3 formed on a protrusive deck after deposition of the particles. The height of the deposition substance 3 easily exceeds the chuck 4 to form contact or binding with the wafer 5 located on the chuck 4. Referring to FIG. 4B, in the second embodiment, due to the arrangement of the barrier surface 122, tip edge 123 and recess 112, during the deposition process, the tip edge 123 can reduce adherence of the deposition particles, the barrier surface 122 can reflect the deposition particles to move away from the wafer 30, and the recess 112 can increase the housing space for holding the deposition particles. Hence although the deposition particles still form a deposition substance 60 on the protective member 12, the height of the deposition substance 60 does not easily exceed the chuck 20 to form contact with the wafer 30 on the chuck 20, thereby can increase the service lifespan of the deposition ring 10.

As a conclusion, in the invention, through the protective member, a great portion of the deposition particles dropping onto the protective member are away from the wafer due to the reflective path provided by the barrier surface, hence can reduce the probability of adhering the deposition particles onto the back of the wafer. Moreover, the barrier surface and circumferential wall form the acute angle between them to form a structure with a gradually increasing bottom, thus can enhance stress resistant capability and overcome the problem of easy fracturing. In addition, the invention also provides the recess with a desired depth to adjust the duration of useable period of the deposition ring. All this indicates that it provides significant improvements over the conventional techniques.

While the preferred embodiments of the invention have been set forth for the purpose of disclosure, they are not the limitation of the invention, modifications of the disclosed embodiments of the invention as well as other embodiments thereof may occur to those skilled in the art. Accordingly, the appended claims are intended to cover all embodiments which do not depart from the spirit and scope of the invention.

What is claimed is:

1. A deposition ring used on thin film deposition equipment which includes a chuck to hold a wafer, the deposition ring being arranged on a circumferential wall of the chuck, and comprising:
an inner ring adjacent to the circumferential wall; and
a protective member jutting from the inner ring and including a circumferential surface opposing the circumferential wall, a barrier surface forming an acute angle with the circumferential surface and a tip edge formed between the circumferential surface and the barrier surface.

2. The deposition ring of claim 1, wherein the inner ring includes an upper surface adjacent to the protective member.

3. The deposition ring of claim 2, wherein the barrier surface includes a curved surface connecting to the upper surface.

4. The deposition ring of claim 2, wherein the barrier surface includes an inclined surface to form an obtuse angle with the upper surface.

5. The deposition ring of claim 2, wherein the inner ring includes a recess to bridge the barrier surface and the upper surface.

6. The deposition ring of claim 5, wherein the recess includes a concave surface with two sides respectively bridging the barrier surface and the upper surface.

7. The deposition ring of claim 5, wherein the recess includes a bottom side spaced from the upper surface at a depth.

8. The deposition ring of claim 2 further including an outer ring which connects to the inner ring and located at one side of the inner ring remote from the circumferential wall.

9. The deposition ring of claim 8, wherein the outer ring includes a jutting detent member connecting to the inner ring and including a detent surface connecting to the upper surface.

10. The deposition ring of claim 9, wherein the outer ring includes an indented isolation groove which is adjacent to the detent member and located at one side of the detent member remote from the inner ring.

11. The deposition ring of claim 1, wherein the wafer covers the tip edge.

12. The deposition ring of claim 1, wherein the tip edge is formed at an elevation lower than that of the wafer.
